(19) United States
(12) Patent Application Publication
(10) Pub. No.: US 2025/0307511 A1
(43) Pub. Date: Oct. 2, 2025

(54) SILICON REPAIR FOR LOGIC TILE ARRAYS IN A MAIN DIE VIA REDUNDANT LOGIC TILES IN AT LEAST ONE OTHER DIE

(71) Applicant: Advanced Micro Devices, Inc., Santa Clara, CA (US)

(72) Inventors: Alexander Sean UNDERWOOD, Austin, TX (US); Karthik Ramu SANGAIAH, Bellevue, WA (US); Ryan Lynn SWANN, Austin, TX (US)

(21) Appl. No.: 18/617,023

(22) Filed: Mar. 26, 2024

(51) Int. Cl. G06F 30/3323; H01L 25/065; H01L 25/18; H10B 80/00

(52) U.S. Cl. CPC G06F 30/3323; H01L 25/0657; H01L 25/18; H10B 80/00

(57) ABSTRACT

An integrated circuit die stack comprises copies of logic tiles of a tiled array architecture of a main die that are located in an interposer die with signal routing configurations provided such that a faulty tile in the main die can be replaced with the redundant logic tile in the interposer die which has the same functions as the faulty tile in the main die. Still another at least one spare active die having redundant tiles therein, may have at least one redundant logic tile different from or the same as the redundant logic tile of the interposer die. Different redundant logic tiles may be located in the same or different at least one spare active die of the die stack. The redundant logic tile may also be used to enhance performance by increasing the number of active processing elements when not needed for replacement of a faulty tile.

### TECHNICAL FIELD

Embodiments of the present disclosure generally relate to integrated circuit packaging of a main die and at least one other die having redundant logic for replacement of defective logic in the main die, and in particular, to configurations of digital logic/processors/memory arranged in a stack for use in integrated circuit packages having integral repair capabilities of defective logic in the main die.

### BACKGROUND

Silicon yield has been and remains an issue in design fabrication of integrated circuit (IC) device products that can result in significant replacement costs or major changes to a final product's available features or loss of any functionality and therefore requiring scrapping the IC device. Many strategies and methodologies have been employed to provide repair capabilities to reduce or avoid errors in silicon IC devices by providing redundant logic paths, alternative routing features, error checking and correcting, and the like.

Tiled compute architectures, e.g., a grid of logic blocks comprising the same elements repeated over and over again. For example, general processing units (GPUs), artificial intelligence (AI) engines (tiny processors), as well as any repeating logic blocks within an architecture, frequently implement yield repair features to prevent a single faulty tile from ruining an otherwise functioning die. Repair features implemented to prevent this often occupy significant area (e.g., redundant logic) on the primary die that could have housed more compute or expand existing features rather than contain dark logic that remains nonfunctional unless needed post fabrication to fix logic issues of the IC die. Improvements to these repair methodologies could greatly increase recovery of lost silicon areas while ideally reducing the architectural impacts on the design that limit improvements elsewhere.

### SUMMARY

In one example of the disclosure, an integrated circuit die stack includes a primary logic die having a plurality of logic tiles interconnected to function as a logic circuit. An active interposer die having a plurality of replacement logic tiles functionally equivalent to the plurality of logic tiles. Signal switches adapted for decoupling a defective one of the plurality of logic tiles from the logic circuit and coupling a functionally equivalent replacement tile to the logic circuit in its place.

In one example of the disclosure, a method for replacing defective logic tiles in an integrated circuit die stack includes determining, in a plurality of logic tiles interconnected to function as a logic circuit of a primary logic die, which logic tile is defective. Decoupling the defective logic tile from the interconnected plurality of logic tiles. Coupling a replacement logic tile from an active interposer die to the interconnected plurality of logic tiles.

In one example of the disclosure, a system of an integrated circuit die stack includes at least one primary logic die having a plurality of logic tiles interconnected to function as a logic circuit. At least one active interposer die having a plurality of replacement logic tiles functionally equivalent to the plurality of logic tiles. Signal switches adapted for decoupling a defective one of the plurality of logic tiles from the at least one logic circuit and coupling a functionally equivalent replacement logic tile to the logic circuit in its place. A memory disposed in the at least one active interposer die.

### BRIEF DESCRIPTION OF THE DRAWINGS

So that the manner in which the above recited features of the present invention can be understood in detail, a more particular description of the invention, briefly summarized above, may be had by reference to examples, some of which are illustrated in the appended drawings. It is to be noted, however, that the appended drawings illustrate only typical examples of this invention and are therefore not to be considered limiting of its scope, for the invention may admit to other equally effective examples.

FIG. 1 illustrates a representative prior art schematic block diagram layout of a primary logic die showing a plurality of interconnected logic tiles.

FIG. 2 illustrates a representative prior art schematic block diagram layout of the primary logic die of FIG. 1 showing a defective logic tile being replaced with a spare logic tile located on the same logic die.

FIG. 3 illustrates a representative prior art schematic block diagram layout of the primary logic die of FIG. 1 showing a defective logic tile being replaced with a spare logic tile located on the same logic die.

FIG. 4 illustrates a representative prior art schematic block diagram layout of the primary logic die of FIG. 1 showing a defective logic tile being replaced with a column (or row) of spare logic tiles located on the same logic die by changing the row or column indices.

FIG. 5 illustrates a schematic isometric block diagram of a main die having logic tiles and another die having substantially the same or similar logic tiles as the main die, according to an example.

FIG. 6 illustrates a schematic isometric block diagram of a main die having logic tiles and two other dice having substantially the same or similar logic tiles as the main die, according to an example.

FIG. 7 illustrates a schematic isometric block diagram of a main die having four zones of logic tiles and another die having substantially the same or similar logic tiles as each zone of the main die, according to an example.

FIG. 8 illustrates an elementary single line schematic diagram of logic tiles and switch boxes, and interconnections therebetween, according to an example.

FIG. 9 illustrates a representative schematic elevational cross-section layout of an integrated circuit (IC) comprising a primary logic die having a plurality of logic tiles and an active interposer die having replacement logic tiles stacked in a three-dimensional IC configuration, according to an example.

FIG. 10 illustrates a representative schematic elevational cross-section layout of an integrated circuit (IC) comprising a primary logic die having a plurality of logic tiles, an active interposer die and at least one replacement tile die stacked in a three-dimensional configuration, according to an example.

FIG. 11 illustrates a representative schematic elevational cross-section layout of an integrated circuit (IC) comprising two primary logic dice having a plurality of logic tiles, an active interposer die, a plurality of replacement tile dice and a plurality of replacement chiplets stacked in a three-dimensional configuration, according to an example.

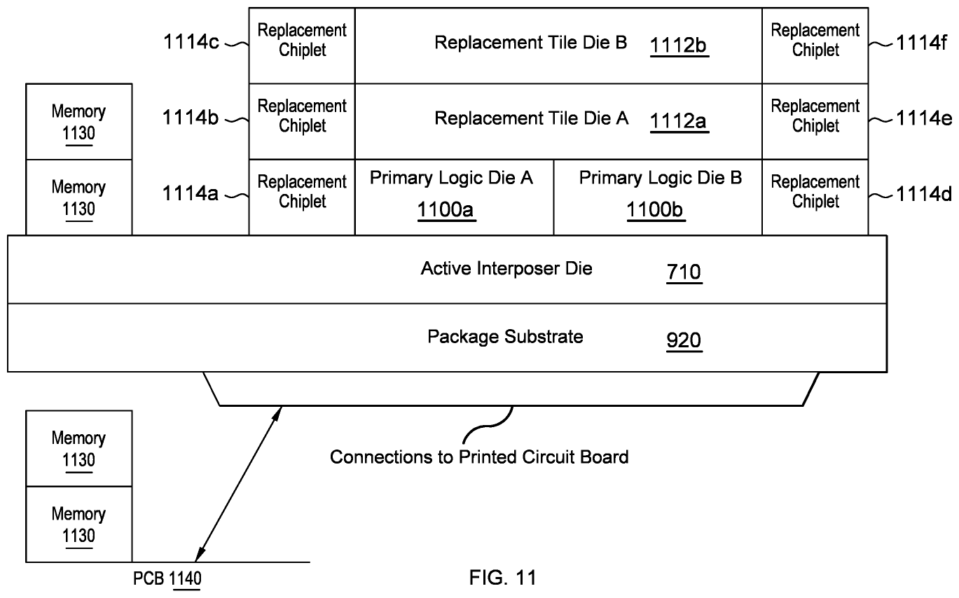

In FIG. 11, a component 1130 is located external to the integrated circuit die stack. The component 1130 exchanges data with the integrated circuit die stack. The component 1130 may be configured as one or more memory IC dies comprising a memory stack that is disposed on the active interposer die 710 or package substrate 710. The component 1130 communicate with one or both of the logic dies 1100A, 1100B via the routings formed through the active interposer die 710 and/or package substrate 710. Optionally, one or more components 1130 such as memory may be located remotely from the chip package that contains the logic dies 1100A, 1100B, for example on a printed circuit board (PCB) 1140. The printed circuit board (PCB) 1140 may be the same PCB to which the chip package that contains the logic dies 1100A, 1100B are mounted, or a different PCB remote from the PCB to which the chip package that contains the logic dies 1100A, 1100B are mounted. The memory IC dies of the component 1130 may be volatile and/or non-volatile memory. In one example, tile switch box configurations may be stored in the one or more memory IC dies of the component 1130 and retrieved during system initial setup and/or after an internal built-in-self-test (BIST) requiring a tile(s) reconfiguration.

To facilitate understanding, identical reference numerals have been used, where possible, to designate identical elements that are common to the figures, and a lower-case letter added where the elements are substantially the same. It is contemplated that elements of one embodiment may be beneficially incorporated in other embodiments.

### DETAILED DESCRIPTION

Various features are described hereinafter with reference to the drawing figures. It should be noted that the drawing figures may or may not be drawn to scale and that the elements of similar structures or functions are represented by like reference numerals throughout the drawing figures. It should be noted that the drawing figures are only intended to facilitate the description of the features of the examples. They are not intended as an exhaustive description of the examples below or as a limitation on the scope of the claims. In addition, an illustrated example need not have all the aspects or advantages shown. An aspect or an advantage described in conjunction with a particular example is not necessarily limited to that example and can be practiced in any other examples even if not so illustrated, or if not so explicitly described. Referring now to the drawing figures, the details of examples are representative layouts schematically illustrated. Like elements in the drawing figures will be represented by like numbers, and similar elements will be represented by like numbers with a different lower-case letter suffix.

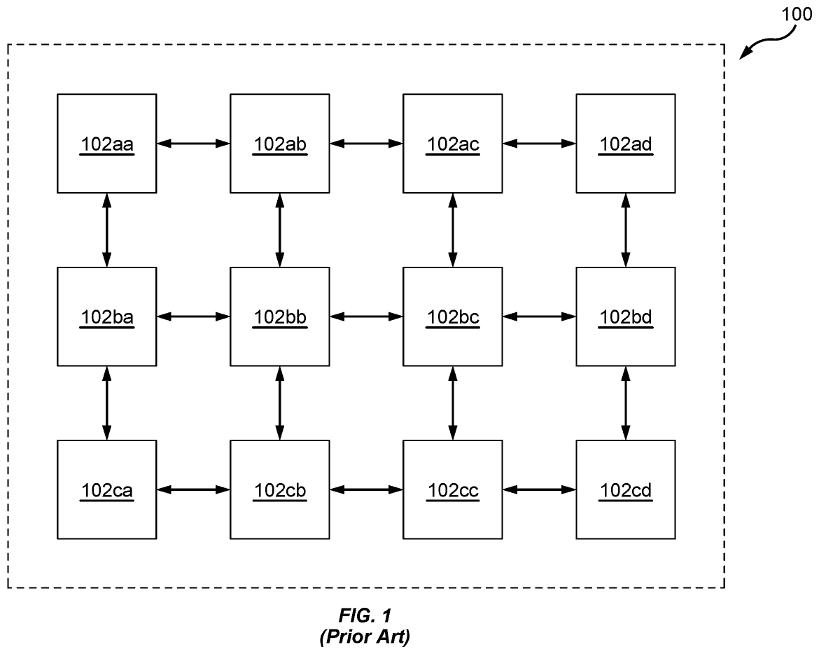

Referring to FIG. 1, depicted is a representative prior art schematic block diagram layout of a primary logic die showing a plurality of interconnected logic tiles. A primary logic die, generally represented by the numeral 100, comprises a plurality of logic tiles 102 arranged and interconnected in a four-by-three matrix. The four-by-three matrix shown is for illustrative purposes only, and the number of logic tiles and the row and column numbers may be of any values. Each logic tile 102 is interconnected to adjacent logic tiles 102.

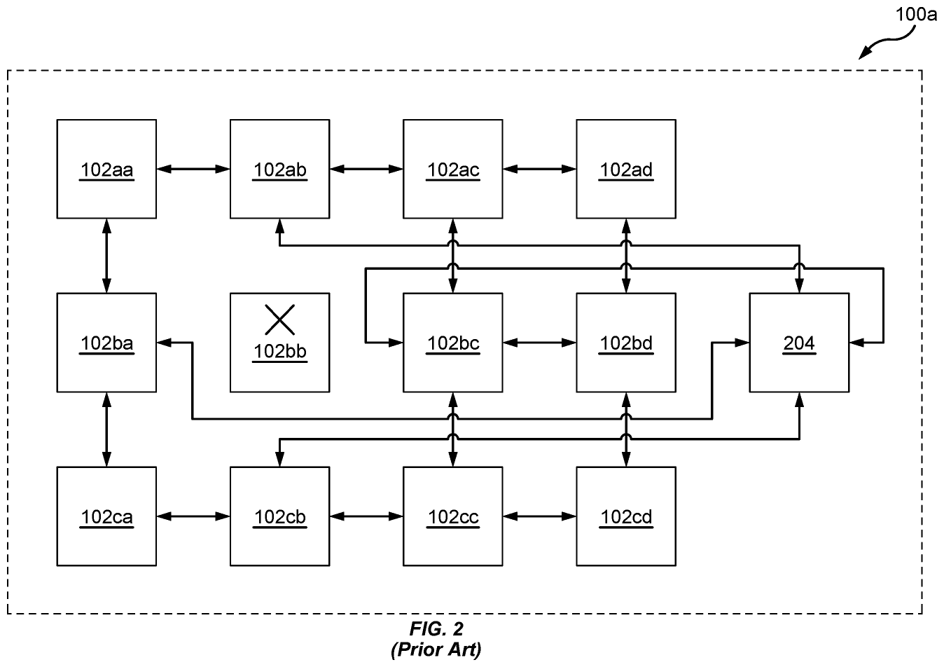

Referring to FIG. 2, depicted is a representative prior art schematic block diagram layout of the primary logic die of FIG. 1 showing a defective logic tile being replaced with a spare logic tile located on the same logic die. To provide repair avenues for faulty tiles a spare tile, e.g., spare tile 204, can be included on the primary die 100a. This would also include routing logic that would allow for the faulty tile to be removed from operation (skipped) and forward all operating and control data intended for that tile to the spare tile, as shown in FIG. 2. This creates long signal paths, however, especially for faulty tiles located at the opposite edge from the spare tile 204, leading to timing issues on these long signal paths and potentially an asymmetrically timed array where not all tiles 102 have the same-latency paths to their neighbor tiles.

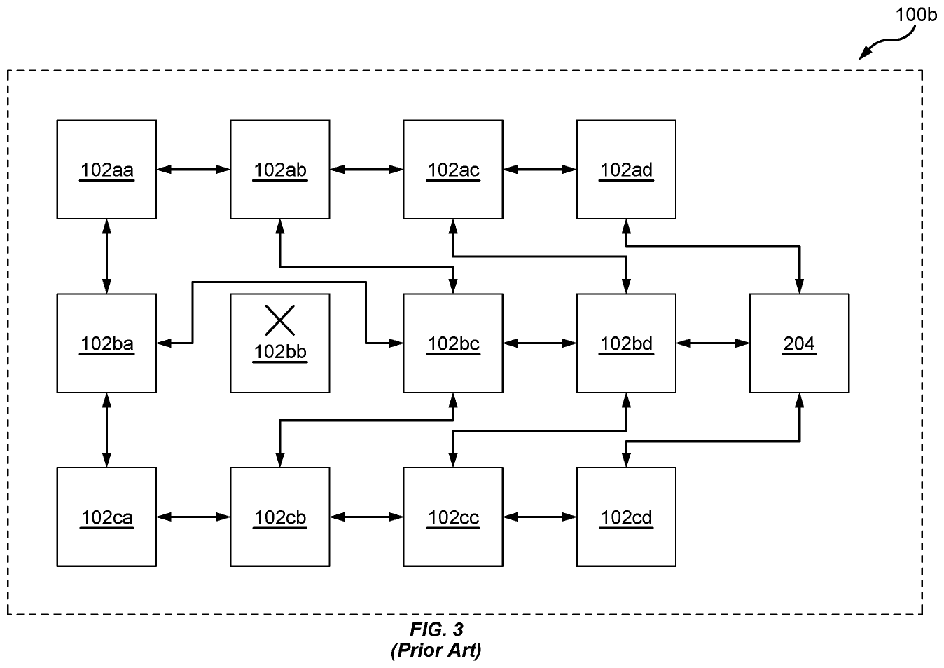

Referring to FIG. 3, depicted is a representative prior art schematic block diagram layout of the primary logic die of FIG. 1 showing a defective logic tile being replaced with a spare logic tile located on the same logic die. To provide repair avenues for faulty tiles a spare tile, e.g., spare tile 204, can be included on the primary die 100b. Alternatively (from FIG. 2), all tiles 102 after the faulty tile 102bb can have their row index decremented with a switching matrix (not shown), allowing the spare tile 204 to take the role of the final tile in the row with the faulty tile. This prevents long signal paths that can break timing but requires more tiles to reroute their communication; neighboring tiles in the row above and below the faulty tile's row will need to reach diagonally to “skip” a tile and access the correctly indexed tile as shown in FIG. 3.

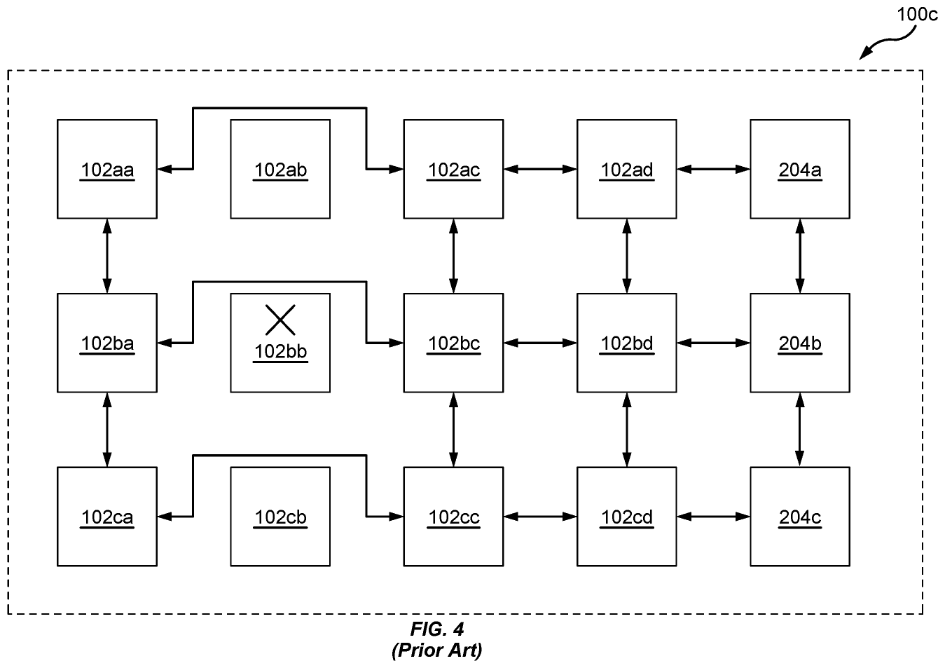

Referring to FIG. 4, depicted is a representative prior art schematic block diagram layout of the primary logic die of FIG. 1 showing a defective logic tile 102bb being replaced with a column (or row) of spare logic tiles 204 located on the same logic die by changing the row or column indices. To provide repair avenues for faulty tiles a column (or row) of spare tiles, e.g., spare tiles 204, can be included on the primary die 100c. This repair method provides a corresponding shift in all tile row or column indices past the disabled tile(s) and eliminates the necessity of diagonal connections between tiles, as is the case when a single tile is bypassed (FIG. 3). However, this method incurs a much higher area cost for what will primarily be dark logic-either the repair column (row) or the column (row) with the lone faulty unit but otherwise functioning tiles. It is also possible to fix multiple faulty tiles with a repair column or row, but only if all the faulty tiles are in the same column or row; faulty tiles spread across more than one column or row would require multiple repair columns or rows, or a finer-grained approach like those described previously and shown in FIGS. 2 and 3.

According to the teachings of this disclosure, redundant copies of logic tiles of a tiled array architecture may be placed inside another active die with routing configurations provided such that a faulty tile in the main die can be replaced by having all of its input-output (I/O) signals re-routed to a redundant logic tile located in the another active die and having the same functions as the faulty tile in the main die. This another active die may be an interposer die located between the main die and an IC connection substrate for connecting the main die circuits to a printed circuit board (PCB). Still another at least one spare active die having redundant tiles therein, may be located above the main die (on the opposite face of the main die from the interposer die to form a dice stack that may have at least one redundant logic tile different from or the same as the redundant logic tile of the interposer die. Different redundant logic tiles may be located in the same or different at least one spare active die stacked on top of each other.

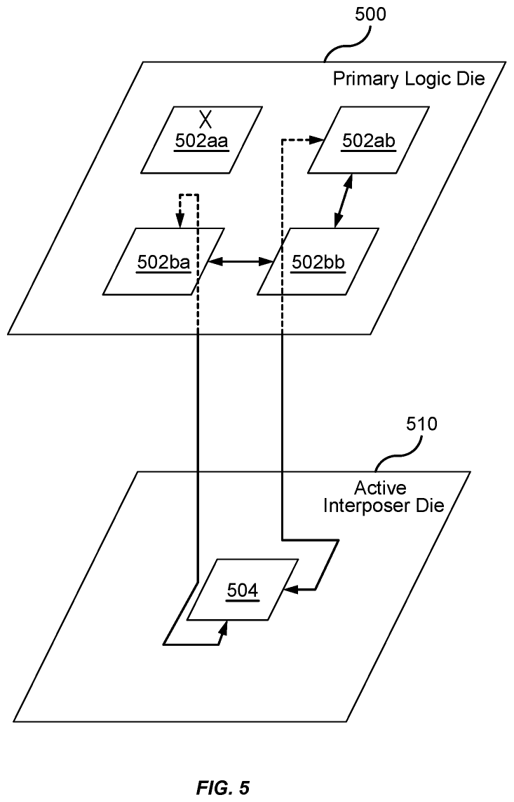

Referring to FIG. 5, depicted is a schematic isometric block diagram of a main die having logic tiles and another die having substantially the same or similar logic tiles as the main die, according to an example. A main die or “primary logic die” 500 comprises logic tiles 502 normally interconnected together as shown in FIG. 1. The other die may be an active interposer die 510 comprising at least one replacement logic tile 504 having substantially the same or similar logic functions as one of the logic tiles 502 of the primary logic die 500. For example, a defective logic tile 502aa of the primary logic die 500 may be replaced with a replacement logic tile 504 of the active interposer die 510. Architecturally, this is the same redundancy strategy as illustrated in FIG. 2, where the change is transparent to all logic tiles in the tile array not immediately adjacent to the faulty logic tile 502aa. However, connecting the replacement logic tile 504 of the active interposer die 510 to the logic tiles 502ba and 502ab of the primary logic die 500, significantly reduces wiring distances for this reconnection repair by taking advantage of a third dimension in the IC die stack design space.

The block diagram of FIG. 5 shows a small two-by-two array of logic tiles 502 in the primary logic die 500, and the replacement logic tile 504 in the active interposer die 510 as the redundancy feature shown in FIGS. 2 and 3 (replacement logic tile 204), with only the relevant wiring shown between the primary logic die 500 and the active interposer die 510. If the faulty tile has boundary connections, those would also need to be re-routed downward or, more likely, re-use the existing micro bumps or through-hole silicon vias (TSVs) that were used to bring the boundary signals from the edge of the tile array of the primary logic die 500 down to the active interposer die 510 for networking and off-chip I/O (not shown). Examples of input/output (I/O) signal switching between selected logic tiles 502 and a replacement logic tile 504 are describe more fully hereinafter.

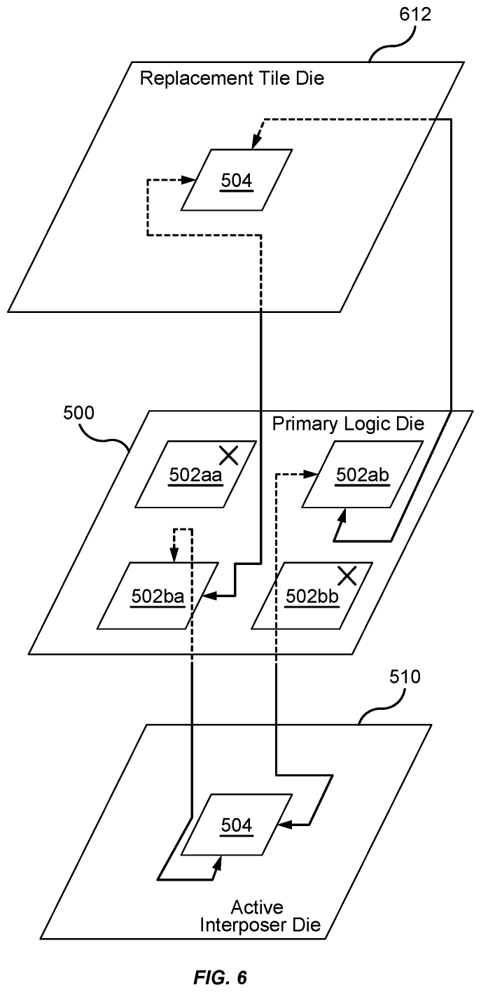

Referring to FIG. 6, depicted is a schematic isometric block diagram of a main die having logic tiles and two other dice having substantially the same or similar logic tiles as the main die, according to an example. A main die or “primary logic die” 500 comprises logic tiles 502 normally interconnected together as shown in FIG. 1. One of the two other dice may be an active interposer die 510 comprising at least one replacement logic tile 504 having substantially the same or similar logic functions as one of the logic tiles 502 of the primary logic die 500. The other one of the two other dice may be a replacement tile die 612 comprising at least one replacement logic tile 606 having substantially the same or similar logic functions as another one of the logic tiles 502 of the primary logic die 500. For example, a defective logic tile 502aa of the primary logic die 500 may be replaced with a replacement logic tile 504 of the active interposer die 510. A defective logic tile 502bb of the primary logic die 500 may be replaced with a replacement logic tile 606 of the replacement tile die 612. It is contemplated and within the scope of this disclosure that a plurality of replacement logic tile dice may provide replacement logic tiles that are substantially the same or similar logic functions as one or more of the logic tiles 502 of the primary logic die 500. The plurality of replacement logic tile dice may be stacked on one side (face) of the primary logic die 500, and the active interposer die 510 may be located on the other side (face) of the primary logic die 500. Switch boxes (not shown) may interconnect the various replacement logic tiles 504 and 606 as needed and disconnect the defective logic tiles 502 that the replacement logic tiles 504 and 606 replace.

In larger, real-world examples where a logic tile array may consist of hundreds or thousands of logic tiles, a single redundant logic tile in the active interposer die provides little benefit over the example tile replacement procedures shown in FIGS. 5 and 6, at best halving the maximum distance from the faulty tile to the redundant logic tile if inter-die layer transportation is ignored. To alleviate this while still retaining as many of the example benefits as possible disclosed herein, the logic tile array of the primary logic die may be divided into groups of logic tiles called zones. Each zone has its own redundant replacement logic tile in an active interposer die, meaning a zone only needs to contain rerouting capabilities for its own subset of the total logic tiles to a dedicated set of endpoints that no other zone will use. This simplifies the routing problem while also decreasing maximum wire lengths between faulty and redundant logic tiles. Additionally, each zone can independently tolerate a faulty logic tile, increasing the chances of reparability for the entire primary logic die (IC device) when more than one logic tile is faulty.

The optimal number of logic tiles in a zone may depend on the logic tile architecture and microarchitecture, fabrication costs, and overall risk tolerance for possible silicon issues. Square or rectangular zones may be easier to implement and maintain due to the shape regularity, and keeping each dimension a multiple of the tile array's respective dimensions prevents asymmetric or irregular zones near the boundaries of the die.

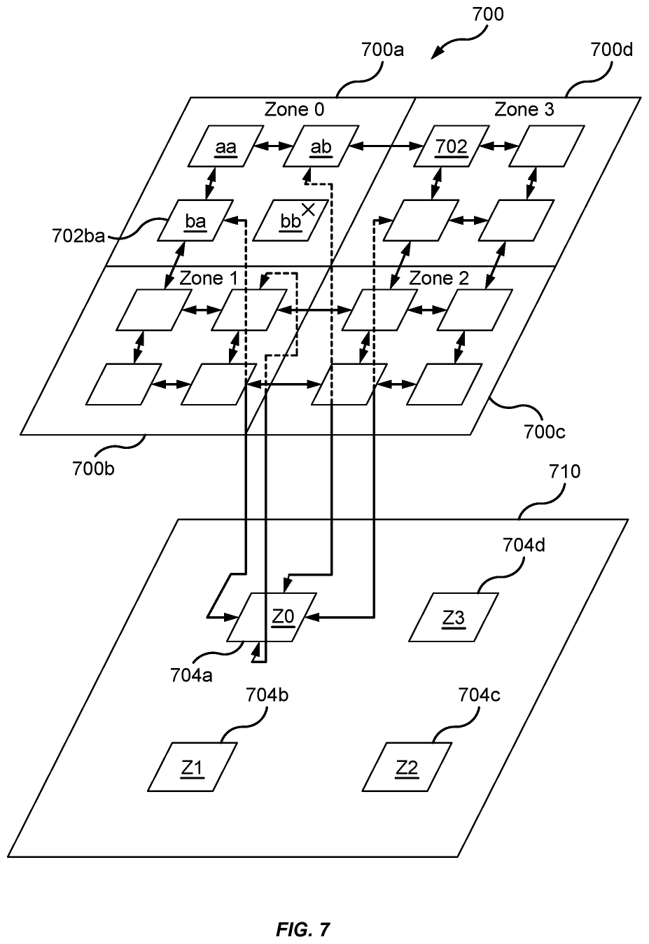

Referring to FIG. 7, depicted is a schematic isometric block diagram of a main die having four zones of logic tiles and another die having substantially the same or similar logic tiles as each zone of the main die, according to an example. A main die or “primary logic die” 700 comprises a plurality of zones 700x (four zones shown 700a, 700b, 700c and 700d) of logic tiles 702 (typical) normally interconnected together as shown in FIG. 1. The another die may be an active interposer die 710 comprising a plurality of replacement logic tiles 704 for each zone 700x and having substantially the same or similar logic functions as at least one of the logic tiles 702 of each zone 700x of the primary logic die 700. FIG. 7 depicts an example four-by-four tile array with four (4) zones total, each two-by-two logic tiles in size. In this example, each redundant logic tile in the active interposer die 710 is labeled “Z #”, where the #symbol indicates which zone the redundant logic tile belongs to as labeled on the primary logic die 700.

A logic tile 702bb in Zone 0 is marked faulty, so the connections are re-routed to the “Z0” redundant tile in the active interposer die 710. For example, a defective logic tile 702bb of the primary logic die zone 700a may be replaced with a replacement logic tile 704a of the active interposer die 710. Architecturally, this is the same redundancy strategy as illustrated in FIG. 5, where the change is transparent to all logic tiles in the tile array not immediately adjacent to the faulty logic tile 702bb. However, connecting the replacement logic tile 704a of the active interposer die 710 to the logic tiles 702ba and 702ab of the primary logic die 700, significantly reduces wiring distances for this reconnection repair by taking advantage of a third dimension in the IC die stack design space.

To reduce the total number of inter-die connections needed to implement this feature, each zone 700x can implement several hardware switch boxes (not shown) which each of the logic tile's input-output (I/O) busses pass through. These switch boxes, may be programmed by firmware or automatically via internal built-in-self-test (BIST) features, and can select which bus(es) needs to descend to the active interposer die 710 to connect with the replacement logic tile 704x and which bus needs to receive the signals ascending from the active interposer die 710 to the primary logic die 700. Small groups of switch boxes may share a set of inter-die connections (not shown) such that no more than one of the busses associated with a particular set of inter-die connections will need the inter-die route for repair purposes (assuming a situation that an example of this disclosure can repair).

Automatic testing of the ICs in the system may be performed, initiation of a BIST, during a system “boot-up” and/or detection of a system operational fault. During the BIST, when a fault in a zone is detected, that zone may be further tested to determine which logic tile is at fault. Once the faulty logic tile is determined, the appropriate busses and switches may be configured for replacement of the faulty logic tile with a replacement logic tile. The positions (states) of the signal switches used for the fault repair may be stored in hardware and/or software tables to maintain the replacement logic tile repair status. The repair status table(s) may be read by a maintenance and/or operating program for guiding appropriate firmware/software operational modifications, and may also be used to disable DC power to the faulty logic tile(s). This capability can provide fault tolerance in a processing system, e.g., self-healing of logic functions.

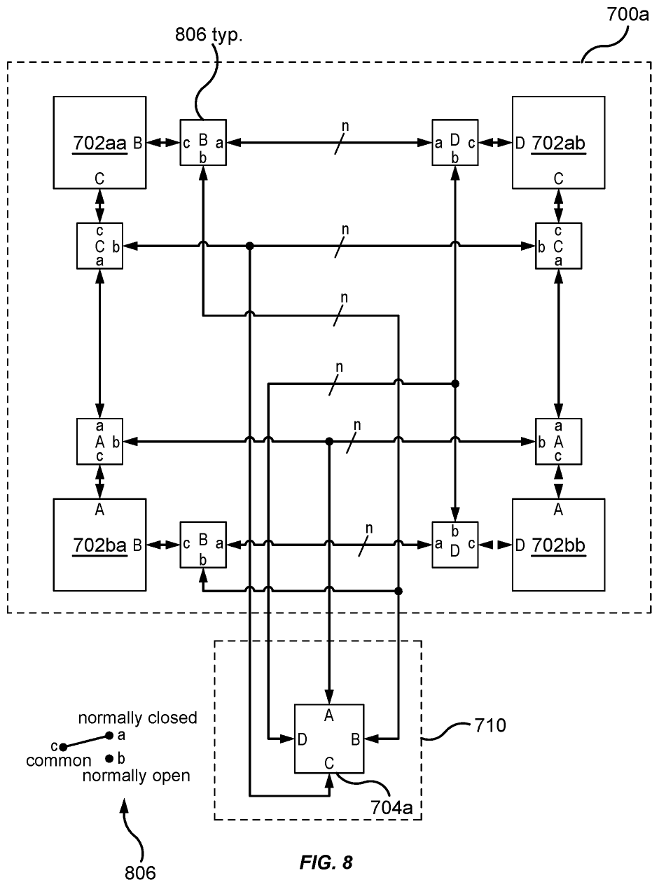

Referring to FIG. 8, depicted is an elementary single line schematic diagram of logic tiles and switch boxes, and interconnections therebetween, according to an example. The switch boxes 806 shown in FIG. 8 may be used in combination with the logic tile replacement examples disclosed hereinabove. Each logic tile 702 may have a switch box 806 for switching input and output signals of the logic tile 702 between adjacent logic tiles 702 or a replacement logic tile 704, e.g., logic tile 702aa shown coupled to logic tiles 702ab and 702ba or if the logic tile 702aa is defective then connecting the replacement logic tile 704a between logic tiles 702ab and 702ba. Each switch box 806 may function as a plurality of double pole switches, where a common “c” is connected to a respective logic tile signal node and is switched to another switch box 806 associated with an adjacent logic tile when at a normally close position “a”. When a logic tile 702 is defective then its associated switch boxes 806 will transfer the signals for the switch boxes 806 associated with the adjacent logic tiles to the replacement logic tile 704a when the normally open position “b” is closed. This would typically be done with tristate logic arranged in a switch matrix configuration located on the primary logic die 500, 700x. What is shown in FIG. 8 is a very rudimentary switching configuration having data busses of n bits.

It is contemplated and within the scope of this disclosure that many different ways of configuring a switching matrix(es) may be utilized, and one having ordinary skill in the art of IC signal switch circuits and the benefit of this disclosure may design appropriate switching circuits. The switching matrix gets more complex when there are many logic tiles and replacement logic tiles used according to the teachings of this disclosure. Power to each logic tile may be gated on and off depending on whether that logic tile is functional or not. Two levels of signal switches may be implemented, a first level of switches on the primary logic die and a second level of switches on the active interposer die. For example, but not limitation to, the logic tiles that are functional will be coupled to adjacent ones of the other functional logic tiles. When a logic tile is defective (not functional) then the first level of switches may isolate (disconnect) the defective logic tile. The signal lines that normally would have connected to the detective logic tile will now be routed to a replacement logic tile in the active interposer die. This may be accomplished through the second level of switches located in the active interposer die (when there is more than one replacement logic tile to select from).

Active interposer dies often use older technologies than a primary logic die for many reasons including fabrication cost savings, technology maturity, and more well-defined and predictable power-performance-area (PPA) characteristics. An active interposer die with a different (older) technology from the primary logic die may present asymmetric compute issues with the newer and faster technologies of the primary logic die, as the version of the logic tile in the older technology in the active interposer die may not be able to reach the same operational data throughput that the primary logic die's tiles can achieve. Therefore, in such a situation, a repaired IC device, according to the teachings of this disclosure, may implement operational speed grades to denote maximum guaranteed product performance, and use of the repair feature to prevent a reduction in the total number of logic tiles available to the customer, even though operation of the repaired IC may require operation at a lower speed grade rank. This potential operating speed reduction may be averted by using replacement logic tiles from a replacement tile die (e.g., die 612 of FIG. 6) having similar technology as the primary logic die. The replacement tile die may be located on the opposite side (face) of the primary logic die. See FIG. 6 and description thereof hereinabove. It is contemplated and with the scope of this disclosure that the replacement tile die may be a plurality of replacement tile dice providing replacement capabilities for each of the logic tiles 702 in each zone 700x of the primary logic die 700 and having substantially the same or similar logic functions thereof. Beyond clock speed, the tile architecture design may determine how effective repair of a logic tile IC device may be:
Independently programmable tile architectures will likely experience few problems as long as there are robust networking primitives available to ensure that dataflow is smooth.
Systolic array architectures may work well with the repair examples of this disclosure unless there is a real-time component that a repair tile with potentially longer network latencies would throw off. Barring that, an otherwise lost IC device may be saved if loss of logic tiles in the array is not tolerable.

Predominately single instruction, multiple data (SIMD) tile arrays may be the most susceptible to issues as each tile is expected to behave in a very predictable manner, including the networking latencies between such data tiles. SIMD describes computers with multiple processing elements that perform the same operation on multiple data points simultaneously. Depending on the level of flexibility included in the overall architecture, care must be taken to make sure that a replacement logic tile(s) doesn't change algorithmic performance in SIMD modes.

Supporting Multiple Clock Domains: Examples disclosed herein may support multiple clock-domains across an IC device, such that one or more zones, e.g., as shown in FIG. 7, may correspond to a particular clock domain. In cases of a fault, the zone 700x with a fault may use a redundant processing element (PE). “PE” is a generic term for a processor (e.g., central processing unit (CPU) core, graphic processing unit (GPU) shader engine/Compute Unit, application specific integrated circuit (ASIC) processor core). In the example shown in FIG. 7, a redundant or backup processing element may reside in a secondary clock domain, e.g., replacement tile 704a of active interposer die 710, which can be used when a fault occurs in the primary clock domain. The secondary clock may be at a slower clock domain than the other non-faulted zones. In cases of multi-tenancy or the execution of multiple kernels distributed across an IC device, a computational process may tolerate a slower clock domain in a faulted zone when using substitution of a replacement logic tile to keep the zone active. Machine learning inference is one such application, where logic die layers may execute in parallel across the IC device and could tolerate some logic die layers operating in a slower clock domain.

Compiler/Scheduler Support: A compiler for such a tiled architecture can receive information about a particular device's repair status and use this information to avoid the potentially slower repair tile in the interposer when mapping timing-sensitive parts of the program and instead use the zones with repair tiles to perform less critical operations or slower, asynchronous parts of the program. Such support may require the operating program to be compiled differently for every instance of a device a user owns, but could provide performance improvements to users who desire an optimally running program. An easier way to manage this without recompiling the program for every device may be to provide device repair status information to a workload scheduler used to manage a cluster of the aforementioned logic tile architectures. Workload schedules can group together devices with lower speeds due to an active repair tile and schedule lower priority work to those devices first while reserving fully functional devices for higher priority jobs. This could also be used in a cloud computational system were slower, repaired devices, comprising a lower tier of products as a service, while the full-speed devices are saved for higher tiers with higher costs per unit of time.

Logic Tile Repair Advantages: Example methods for logic tile repair disclosed herein provide most of the benefits of existing redundant logic tile silicon repair methods but without occupying significant space on the primary logic die. Additionally, because the redundant logic provided, according to the examples disclosed herein, uses three-dimensional (3D) stacked techniques via an active interposer die (FIG. 5) and/or replacement tile die (FIG. 6) that provides for connections to the redundant replacement tiles that are significantly shorter compared to alternative prior art solutions that must work across a single, two-dimensional die, often leading to long signal paths and difficult (degradation in) signal timing.

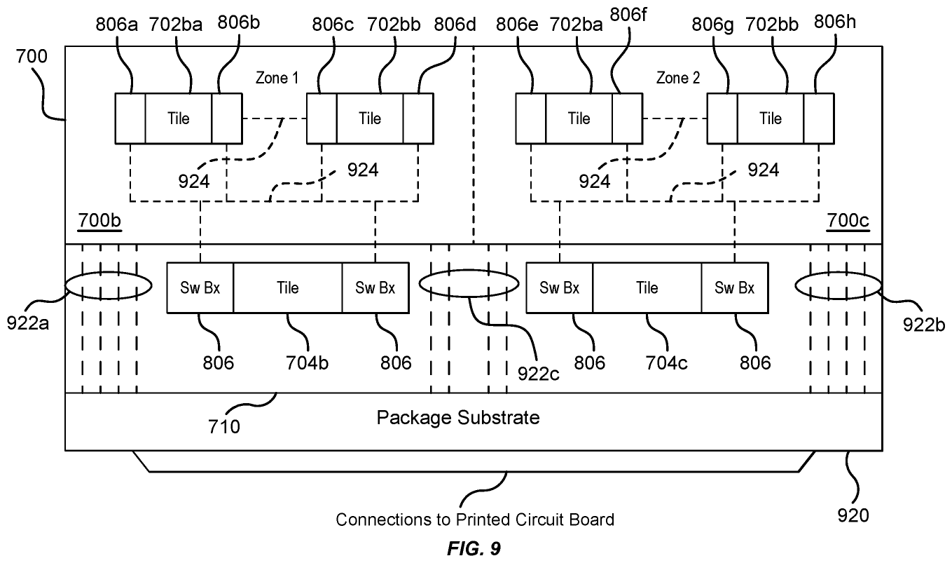

Referring to FIG. 9, depicted is a representative schematic elevational cross-section layout of an integrated circuit (IC) comprising a primary logic die having a plurality of logic tiles and an active interposer die having replacement logic tiles stacked in a three-dimensional IC configuration, according to an example. A primary logic die 700 may comprise a plurality of logic tiles 702 and signal switches 806 coupling the plurality of logic tiles 702 together. The primary logic die 700 may be configured into zones 700x having subsets of the logic tiles 702 and signal switches 806 (zones 700b and 700c shown). An active interposer die 710 may comprise at least one replacement logic tile 704 for each zone 700x of logic tiles 702 of the primary logic die 700. The at least one replacement logic tile 704 may be associated with the logic tiles of a respective zone 700x of the primary logic die 700. E.g., for each zone of logic tiles of the primary logic die 700 there may be at least one replacement logic tile 704 in the active interposer die 710. A plurality of switch boxes 806 may be used to route signal lines 924 between operational logic tiles 702, and disconnect a defective logic tile 702x from the operational logic tiles 702. Then that defective logic tile 702x will be replaced with a replacement logic tile 704x located in the active interposer die 710 by connecting it to the associated operational logic tiles 702 previously disconnected from the defective logic tile 700x.

Interconnections 922 (e.g., TSVs) may be provided in the active interposer die 710 for delivery of DC power and signals from a package substrate 920 having external connections to a printed circuit board (PCB) and the primary logic die 700. The signal lines 924 may also pass between the primary logic die 700 and the active interposer die 710 to respective switch boxes 806.

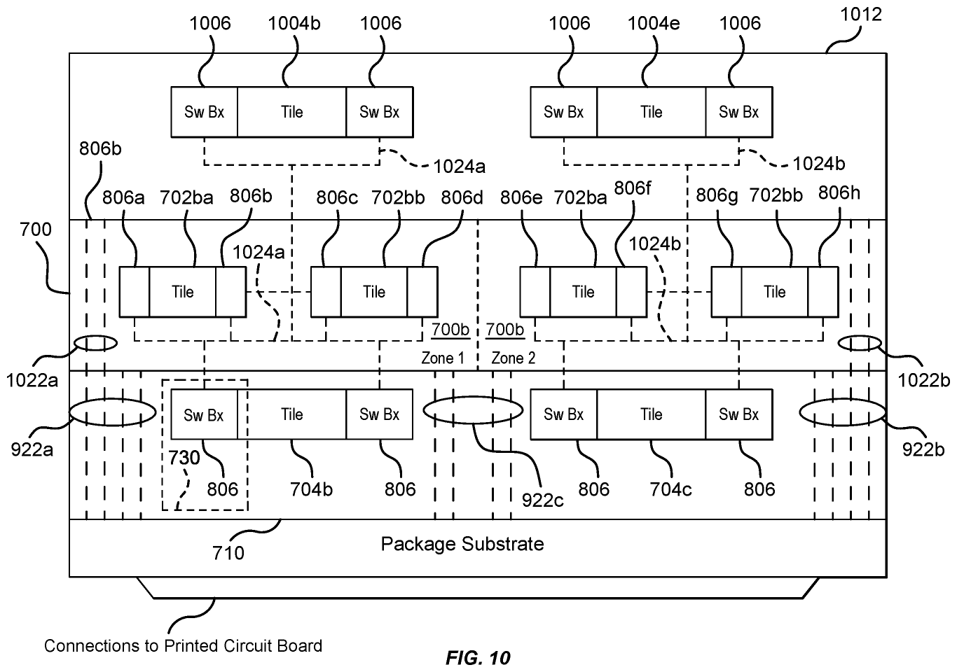

Referring to FIG. 10, depicted is a representative schematic elevational cross-section layout of an integrated circuit (IC) comprising a primary logic die having a plurality of logic tiles, an active interposer die and at least one replacement tile die stacked in a three-dimensional configuration, according to an example. The configuration and operation of the primary logic die 700 and the active interposer die 710 are substantially the same as shown in FIG. 9 and described hereinabove. At least one replacement tile die 1012 may be added to the IC die stack on the opposite side (face) of the primary logic die 700 from the active interposer die 710. The logic tiles 1004 of the at least one replacement tile die 1012 may be of the same technology and capabilities as the logic tiles 702 in the primary logic die 700. Therefore, an operating speed degradation of the IC may not be necessary when a replacement tile 1004 is used with the logic tiles 702 of the primary logic die 700. Having a plurality of replacement tile dice 1012 can allow the availability of different replacement logic tiles 1004 to match different logic tiles that may be found in the primary logic die 700.

The at least one replacement tile die 1012 may comprise at least one replacement logic tile 1004 for each zone 700x of logic tiles 702 of the primary logic die 700. The at least one replacement logic tile 1004 may be associated with the logic tiles of a respective zone 700x of the primary logic die 700. E.g., for each zone of logic tiles 702 of the primary logic die 700 there may be at least one replacement logic tile 1004 in the at least one replacement tile die 1012. A plurality of switch boxes 806 may be used to route signal lines 1024 between operational logic tiles 702, and disconnect a defective logic tile 702x from the operational logic tiles 702. Then replace that defective logic tile 702x with a replacement logic tile 1004x located in the at least one replacement tile die 1012 by connecting to the associated operational logic tiles 702 previously disconnected from the defective logic tile 702x.

Interconnections 1022 (e.g., TSVs) may be provided in the primary logic die 700 for delivery of DC power and signals from the active interposer die 710. The signal lines 1024 may also pass between the primary logic die 700 and the at least one replacement tile die 1012 to respective switch boxes 1006. In addition to the use of replacing defective tiles 702, the replacement logic tiles 1004 of the at least one replacement tile die 1012 may be actively used to enhance performance of the primary logic die 700 by increasing the number of active processing elements (logic tiles). Thus, when there are few or no defective logic tiles 702 that would have to be replace, then one or more of the replacement tiles 1004 may be added to the processing power of the IC, e.g., increase the number of processing elements (PEs) of the primary logic die 700.

A logic tile 702 may comprise one or more processing elements (PEs), e.g., central processing unit (CPU) core, graphics processing unit (GPU), shader engine/compute unit, application specific integrated circuit (ASIC) processor core, arithmetic logic unit (ALU), digital signal processor (DSP), field programmable gate array (FPGA), coarse grained reconfigurable array (CGRA) neural processing unit, tensor processing unit and the like. It is contemplated and within the scope of this disclosure that a logic tile 702 may be comprised of a plurality of PEs, e.g., multi-core CPUs, a reduced instruction set computer (RISC), a microcontroller, a microprocessor, dynamic and/or static memory with controller. It is also contemplated and within the scope of this disclosure that a group (number) of logic tiles 702 having a least one defective PE may be replaced by an equivalent group (number) of replacement tiles 704 or 1004 to restore operation of the IC. A replacement logic tile 704 or equivalent group of replacement tiles 704 may further be utilized to increase the operating power of the IC when not needed as a replacement for a defective logic tile 702. Therefore, the granularity of a logic tile 702 or group of logic tiles 702 in an IC may be selected by application or use, and is not limited in size or complexity.

Referring to FIG. 11, depicted is a representative schematic elevational cross-section layout of an integrated circuit (IC) comprising two primary logic dice having a plurality of logic tiles, an active interposer die, a plurality of replacement tile dice and a plurality of replacement chiplets stacked in a three-dimensional configuration, according to an example. The configuration and operation of the primary logic dice 1100, the active interposer die 710 and at least one replacement tile die 1112 are substantially the same as shown in FIGS. 9 and 10, and described hereinabove. The active interposer die 710 may provide replacement logic tiles 704 for all logic tile zones of both primary logic dice 1100 and may further bridge signal operation between the primary logic dice 1100a and 1100b, and/or a plurality of replacement chiplets 1114. It is contemplated and within the scope of this disclosure that more than two primary logic dice 1100 may be included in the IC and coupled to one or more active interposer dice 710. Not shown in FIG. 11, but are functionally the same as shown in the previous FIGS. and described above, are the logic tiles 702 in the primary logic dice 1100, replacement logic tiles 704 in the active interposer die 710, replacement logic tiles 1004 in the at least one replacement tile die 1112, and signal switch boxes 806.

The plurality of replacement chiplets 1114 may provide replacement logic and/or a plurality of processor elements (PEs) configured as a subsystem, e.g., multicore processor, microcontroller, artificial intelligence (AI) processors and the like. These replacement chiplets 1114 may also be used to replace defective tiles or subsystems in the primary logic dice 1100, and/or added to enhance performance of the functions of the primary logic dice 1100 when not needed as replacement logic. This is advantageous in replacement of defective systolic processors. Signal line interconnections, DC power and grounds may be provided as shown in the above FIGS. and descriptions thereof. Ones of the plurality of replacement chiplets 1114 may also be used to replace other ones the plurality of replacement chiplets that are defective.

A memory 730, e.g., volatile and/or non-volatile, may be included in the active interposer die 710 for storing tile switch box configurations during system initial setup and/or after an internal built-in-self-test (BIST) requiring a tile(s) reconfiguration. Therefore, it is contemplated and within the scope of this disclosure that all examples described hereinabove may incorporate such a feature in the active interposer dies thereof. A plurality of main and interposer dice may be configured into a single integrated circuit (IC) die stack, with memory in each interposer die and/or a common, to the IC die stack, memory for storing the tile switch box configurations as described hereinabove.

For the examples disclosed above, connections between the vias (TSVs) of each die may be done with lower resistance metal bonding pads, e.g., hybrid-bonding, copper hybrid-bonding instead of using microbumps in the power delivery paths and may significantly lower resistance of the electrical connections. This solves a significant voltage drop problem associated with using microbumps for electrical power circuit connections. An added benefit is elimination of the layer-to-layer (D2D) layers between the silicon wafers, allowing direct metal-to-metal electrical connections (hybrid-bonding) between layer layers, thereby further reducing the resistance of connections therebetween. In addition, the layer stack thickness will be reduced and heat transfer improved therethrough. The various semiconductor dice are illustrated or otherwise presumed to be “face down” (e.g., back end of line—BEOL metal layers facing toward the bottom of the stack, bulk silicon/backside facing upward toward the top of the stack). However, different examples may utilize one or more chiplets or other silicon components in “face up” orientations as well.

As will be appreciated by one skilled in the art and having the benefit of this disclosure, the examples disclosed herein may be embodied as a system, method, apparatus, or computer programmed product. Accordingly, aspects may take the form of an entirely hardware embodiment, an entirely software embodiment (including firmware, resident software, micro-code, etc.) or an example embodiment combining software and hardware aspects that may all generally be referred to herein as a “circuit,” “module” or “system.” Furthermore, aspects may take the form of a computer program product embodied in one or more computer readable medium(s) having computer readable program code embodied thereon.

While the foregoing is directed to example embodiments of the present invention, other and further example embodiments of the invention may be devised without departing from the basic scope thereof, and the scope thereof is determined by the claims that follow.

What is claimed:

1. An integrated circuit (IC) die stack, comprising:
a primary logic die having a plurality of logic tiles interconnected to function as a logic circuit;
an active interposer die having a plurality of replacement logic tiles functionally equivalent to the plurality of logic tiles; and
signal switches adapted for decoupling a defective one of the plurality of logic tiles from the logic circuit and coupling a functionally equivalent replacement logic tile to the logic circuit in its place.

2. The IC die stack according to claim 1, wherein
the signal switches comprise a first set in the primary logic die and a second set in the active interposer die;
the first set of signal switches decouple the defective one of the plurality of logic tiles from the logic circuit and couple the logic circuit to the second set of signal switches; and
the second set of signal switches couple a replacement logic tile, from the plurality of replacement logic tiles, to the first set of signal switches, whereby the replacement logic tile is coupled to the logic circuit.

3. The IC die stack according to claim 1, wherein
the plurality of logic tiles are divided into a plurality of zones in the primary logic die; and
at least one of the plurality of replacement logic tiles is associated with each zone of logic tiles in the primary logic die.

4. The IC die stack according to claim 3, wherein
the signal switches comprise a first set in each zone of the primary logic die and a second set for each zone in the active interposer die;
the first set of signal switches decouple the defective one of the plurality of logic tiles in a zone from the logic circuit and couple the logic circuit to the second set of signal switches associated with that zone; and
the second set of signal switches associated with that zone couple the replacement logic tile associated with that zone to the first set of signal switches in that zone, whereby the replacement logic tile is coupled to the logic circuit.

5. The IC die stack according to claim 2, further comprising:
at least one replacement tile die located on an opposite side of the primary logic die from the active interposer die;
the at least one replacement tile die has a plurality of replacement logic tiles functionally equivalent to at least one of the plurality of logic tiles in the primary logic die; and
a third set of the signal switches in the at least one replacement tile die, wherein the third set of the signal switches couple the replacement logic tile in the at least one replacement logic tile die to the first set of signal switches in the primary logic die such that the replacement logic tile of the at least one replacement tile die is coupled to the logic circuit in place of the defective logic tile.

6. The IC die stack according to claim 5, wherein
the plurality of logic tiles are divided into a plurality of zones in the primary logic die; and
at least one replacement logic tile of the at least one replacement tile die is associated with each zone of logic tiles in the primary logic die.

7. The IC die stack according to claim 6, wherein
the signal switches comprise a first set in each zone of the primary logic die and a third set for each zone in the at least one replacement tile die;
the first set of signal switches decouple the defective one of the plurality of logic tiles in a zone from the logic circuit and couple the logic circuit to the third set of signal switches associated with that zone; and
the third set of signal switches associated with that zone couple the replacement logic tile associated with that zone to the first set of signal switches in that zone, whereby the replacement logic tile is coupled to the logic circuit to replace the defective one of the plurality of logic tiles in that zone.

8. The IC die stack according to claim 2, further comprising:
a plurality of primary logic dice each having a plurality of logic tiles interconnected to function as a plurality of logic circuits, and
a plurality of replacement tile dice, each replacement tile die associated with one of the plurality of primary logic dice.

9. The IC die stack according to claim 1, wherein the logic circuit is selected from the group consisting of any one or a combination of a microcontroller, a microprocessor, a mixed signal processor, a central processing unit (CPU), a programmable logic array (PLA), an application specific integrated circuit (ASIC), a digital signal processor (DSP), coarse grained reconfigurable array (CGRA), a graphics processing unit (GPU), a field programmable gate array (FPGA), neural processing unit and tensor processing unit.

10. The IC die stack according to claim 1, wherein replacement logic tiles not used for repair of defective logic tiles are coupled to the logic circuit for increased operating performance thereof.

11. The IC die stack according to claim 2, further comprising a plurality of primary logic dice each having a plurality of logic tiles interconnected to function as a plurality of logic circuits.

12. The IC die stack according to claim 11, wherein:
at least one replacement tile die located on an opposite side of the plurality of primary logic dice from the active interposer die;
the at least one replacement tile die has a plurality of replacement logic tiles functionally equivalent to at least one of the plurality of logic tiles in the plurality of primary logic dice; and
a third set of the signal switches in the at least one replacement tile die, wherein the third set of the signal switches couple the replacement logic tile in the at least one replacement logic tile die to the first set of signal switches in the primary logic die such that the replacement tile of the at least one replacement tile die is coupled to the logic circuit in place of a defective logic tile.

13. The IC die stack according to claim 12, further comprising a plurality of replacement chiplets, each chiplet having a plurality of logic tiles interconnected to function as a chiplet logic circuit.

14. The IC die stack according to claim 13, wherein the chiplet logic circuit from at least one of the plurality of replacement chiplets is adapted for replacing a defective portion of at least one of the logic circuits of the plurality of primary logic dice.

15. The IC die stack according to claim 14, wherein the chiplet logic circuit from at least one of the plurality of replacement chiplets is adapted for adding logic to at least one of the logic circuits of the plurality of primary logic dice.

16. A method for replacing defective logic tiles in an integrated circuit (IC) die stack, comprising:
determining, in a plurality of logic tiles interconnected to function as a logic circuit of a primary logic die, which logic tile is defective;
decoupling the defective logic tile from the plurality of interconnected logic tiles; and
coupling a replacement logic tile from an active interposer die to the plurality of interconnected logic tiles.

17. The method according to claim 16, wherein:
decoupling the defective logic tile from the plurality of interconnected logic tiles with a first set of signal switches in the primary logic die; and
coupling the replacement logic tile to the plurality of interconnected logic tiles with a second set of switches in the active interposer die through the first set of signal switches.

18. A system, comprising:
an integrated circuit (IC) die stack comprising:
at least one primary logic die having a plurality of logic tiles interconnected to function as a logic circuit,
at least one active interposer die having a plurality of replacement logic tiles functionally equivalent to the plurality of logic tiles, and
signal switches adapted for decoupling a defective one of the plurality of logic tiles from the at least one logic circuit and coupling a functionally equivalent replacement logic tile to the logic circuit in its place; and
a component external to the integrated circuit die stack, wherein the component exchanges data with the integrated circuit die stack.

19. The system according to claim 18, wherein the component is memory storing configurations of the signal switches.

20. The system according to claim 19, wherein the configurations of the signal switches are determined during a built-in-self-test (BIST) of the at least one primary logic die.
